(19) United States
(12) Patent Application Publication
(10) Pub. No.: US 2005/0156236 A1
(43) Pub. Date: Jul. 21, 2005

(54) MOS transistor with a three-step source/drain implant

(76) Inventors: Mahalingam Nandakumar, Richardson, TX (US); Seetharaman Sridhar, Richardson, TX (US); Mark S. Rodder, University Park, TX (US)

Correspondence Address: TEXAS INSTRUMENTS INCORPORATED, P O BOX 655474, M/S 3999, DALLAS, TX, 75265, US

(21) Appl. No.: 10/979,693

(22) Filed: Nov. 1, 2004

Related U.S. Application Data
(60) Provisional application No. 60/530,927, filed on Dec. 19, 2003.

(51) Int. Cl. H01L 29/94; H01L 21/338

(52) U.S. Cl. 257/344; 438/306; 438/307; 257/335; 257/336; 257/408

(57) ABSTRACT

A new MOS transistor is described. The transistor has a source/drain region that comprises 3 portions. Each portion is the result of an separate ion implant step. The combination of the three portions of the source/drain region yields a transistor of superior performance with high drive current, low sub-threshold current and gate-edge leakage.

### BACKGROUND OF THE INVENTION

This invention relates to field of semiconductor device fabrication and particularly relates to MOS transistor source/drain engineering.

### DESCRIPTION OF THE RELATED ART

One of the most popular integrated circuit elements for the past several decades has been the Metal-Oxide-Semiconductor (MOS) transistor. In most applications, MOS transistors serve as voltage controlled current switches.

The fundamental principle of MOS transistor operation is well known in the art of semiconductor devices. A MOS transistor has four terminals: it has a gate terminal, a source terminal, a drain terminal and a back-gate terminal. Transistor current passes from the drain terminal to the source terminal inside the transistor through a channel region, which in an enhancement MOS transistor is sandwiched between an oxide region next to the top gate region and a transistor body region, separated by a depletion region on each side. The body region is contacted to the back gate.

Conventional MOS transistors are built with the source/drain terminals electrically and physically symmetric with respect to the gate region. The description of the present invention, therefore, will not distinguish between the source and the drain terminals and they will hence be grouped as source/drain until otherwise specified. The voltages at the gate terminal and at the back-gate terminal control the current passage between the source/drain terminals.

There are two general types of MOS transistors depending on the polarity of the dopant placed in the various portions of the transistors. PMOS transistors turn on current flows between the source terminal and the drain terminal with a negative gate-voltage with respect to the source; NMOS transistors turn on with a positive gate-voltage with respect to the source. The gate voltage at which a MOS transistor turns on is said to be the transistor's threshold voltage (Vt), voltages below Vt in magnitude are termed sub-threshold voltages.

An ideal electrical switch would be capable of passing current the instant it is turned on and completely shutting off the current the moment it is turned off. Modem MOS transistors deviate from this ideal behavior in several aspects:

First, the current flow through the transistor does not respond to the gate signal instantly. There are various parasitic resistance and capacitance components associated with the transistor structure that will cause a finite delay in switching the transistor on and off. Reduction of the parasitic resistance and capacitance through device engineering improves the transistor switching speed. The parasitic resistance in series with the channel includes source/drain contact resistance, source/drain spreading resistance, source/drain extension (SDE) resistance. Parasitic capacitance includes source/drain capacitance (Cj), gate/drain overlap capacitance and fringing capacitance.

Secondly, the parasitic series resistance causes a finite drop in drain-to-source and gate-to-source voltages and lowers the amount of current (Idrive) flowing between the source/drain terminals.

Thirdly, a finite amount of current flows in the MOS transistor when it is turned off. This current is referred to in the art as off current or Ioff. Ioff usually translates to standby power loss. Thus, one of the key goals of transistor design is to lower Ioff.

Ioff comprises two components—the subthreshold leakage current that flows through the channel from the source to the drain, and the gate-edge leakage (GEDL) current that flows between the drain and the substrate.

One method of lowering Ioff is to lower the subthrehold leakage by increasing the dopant concentration in the channel. The increased doping, however, increases the electric field at the source/drain junction edge under the gate and which in turn leads to increased gate-edge leakage (GEDL). Therefore, in a non-optimized transistor, GEDL current can become a substantial portion of the off current Ioff (10-50%). Thus channel doping increase to lower subthreshold leakage becomes counter-productive and leading to increased leakage (Ioff).

A traditional approach to lower Ioff without increasing GEOL is to use graded source/drain extension junctions by ion-implantation at low dose and high energy. However this approach increases the spreading resistance and lowers the inversion capacitance and degrades the transistor performance. So an optimal source-drain design is needed to maintain performance and at the same time lower Ioff and GEDL.

This invention proposes a transistor with an optimized source and drain design and the associated process for fabricating it.

### SUMMARY OF THE INVENTION

It is the object of this invention to provide an improved MOS transistor structure with a lower GEDL and higher Idrive.

In accordance with one embodiment of the invention, the objective can be achieved with a MOS transistor with a source/drain region that have three portions. A first portion of the source/drain region has a first dose of source/drain dopant, implanted at a first implant energy advantageous to control the subthreshold current (Ioff) of the transistor. A second portion of the source/drain region has a second dose of dopant, implanted at a second implant energy advantageous to setting the sheet resistance of the source/drain region and the inversion capacitance. The portion may be further constructed with a two-part implant technique. A third portion of the source/drain region having a third dose, implanted at a third implant energy advantageous to set the junction capacitance of the source/drain region to the semiconductor substrate.

### BRIEF DESCRIPTION OF THE DRAWINGS

FIG. 1 depicts the cross section view of a MOS transistor of the present invention.

FIG. 2 depicts the cross section view of a MOS transistor of the present invention and the composition of the source/drain portions.

### DETAIL DESCRIPTION OF SPECIFIC EMBODIMENT

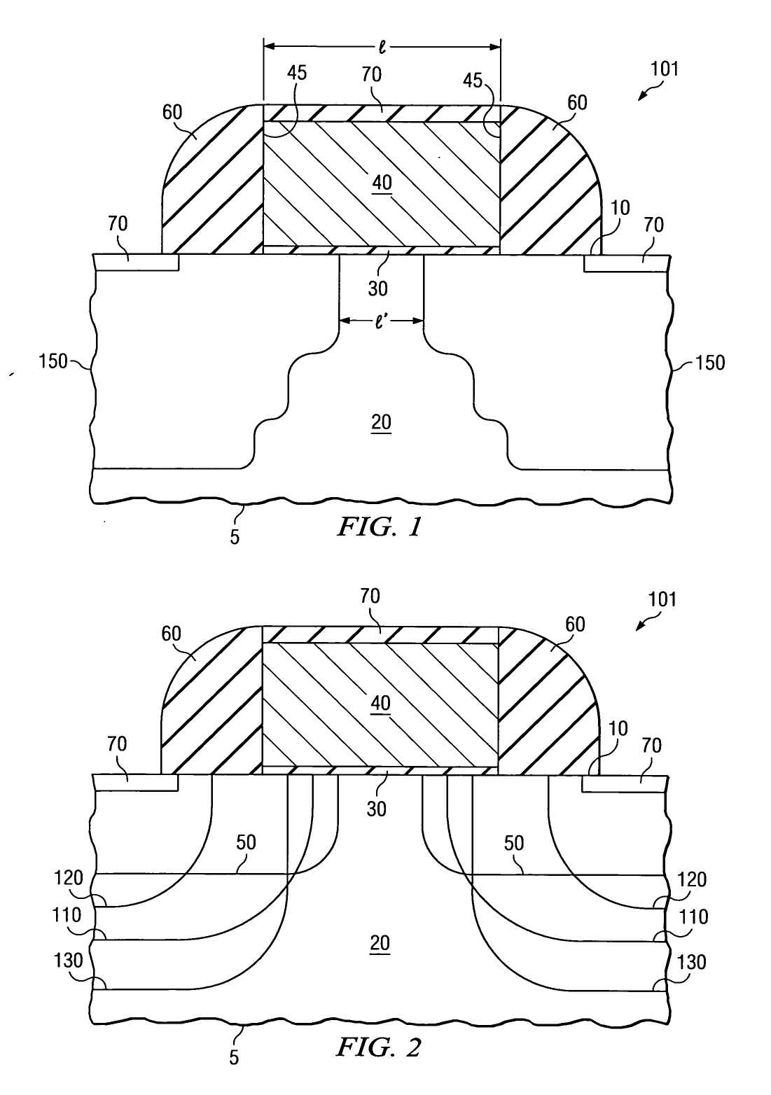

Referring to FIG. 1, a PMOS transistor 101 that utilizes the source/drain structure of the present invention is illustrated in a cross section form. The section sectional drawing is only for illustration purpose. The transistor portions in the drawing are not proportional to scale. The invention is not limited to PMOS transistors built on silicon substrate as it is applicable to other semiconductor devices such as NMOS transistors and other semiconductor materials such as SiGe and semiconductor compound materials.

FIG. 1 depicts a PMOS transistor 101 formed on a silicon substrate 5, the back-gate terminal communicates with a region 20 in the silicon substrate 5 that is doped with phosphorous. The gate terminal 40 is formed on the surface 10 of the silicon substrate 5 and is made of polycrystalline silicon material. Other conductive and semiconductive materials may also be used to form the gate electrode. The width of the gate electrode 1, defines the channel, the apparent distance that the mobile charge-carriers—holes in the case of PMOS, need to traverse when the transistor is in the on state. The actual effective channel length is somewhat shorter than 1.

Below the gate electrode 40 on the surface 10 is a dielectric layer 30. The gate dielectric insulates the gate electrode 40 electrically from the silicon substrate 5. In this embodiment, the gate dielectric 30 is formed with silicon dioxide. One may use other dielectric materials to form the gate dielectric.

The gate electrode 40 has two opposing sidewalls 45 on which sidewall spacers 60 are formed. In this embodiment, the sidewall spacers 60 are formed with silicon dioxide. Other dielectric material may also be used to form the sidewall spacers. The sidewall spacers may also be a multileveled structure of varying materials.

The sidewall spacers 60 serve multiple purposes in the operation of the transistor 101. One purpose is to provide an electrical separation between the silicided regions 70. Another purpose is to provide an ion implant mask during the source/drain formation. The source/drain regions, delineated by the boundary 150 and the surface of the silicon substrate 10, are the two terminals through which the transistor current is designed to flow when a voltage signal greater than Vt is applied to the gate electrode 40.

The source/drain regions of PMOS transistors, especially those with gate electrode l shorter than 0.2 μm, are commonly formed by an ion implantation technique, which is used repeatedly throughout the CMOS fabrication process for other purposes also. For example, it is used for setting the threshold voltage (Vt), for forming the source/drain extension (SDE), for preventing channel punch through, etc. This invention directs to a source/drain ion implantation technique that results in a transistor structure with superior Idrive and Ioff performance. The structure is depicted in FIG. 2.

FIG. 2 depicts the components of the source/drain regions formed utilizing the ion implant technique. In this embodiment, there are 5 portions in each source/drain region 150. The portion 70 is the metal silicide region. The metal that forms the silicide alloy may be titanium, cobalt, nickel or other suitable metals. The portion 50 is the source/drain extension (SDE) region. The portion extends underneath the gate electrode 40. The distance l′ between the two SDE regions defines the effective channel length of the transistor. In this embodiment, the SDE 50 is formed by a 3-step ion implant process. One step is a pre-amorphization antimony implant (not shown) at 5-30 keV, preferably 20 keV, another step is BF₂ implant of a dose between 1E14 and 1E15 ions/cm², preferably 3E14 ions/cm² at an energy between 2 and 10 keV, preferably 6 keV, another step is the phosphorous pocket implant (not shown) between 1E13 and 1E14 ions/cm², preferably 6.6E13 ions/cm², at an energy between 20 and 60 keV, preferably 40 keV, and at between 0 and 30 degree angles, preferably 15 degrees. All three implants are performed following the gate 40 formation and prior to the sidewall spacer 60 formation.

Following the sidewall spacer formation, three additional ion implants are performed to complete the source/drain implant flow. The purpose of the additional three ion implant steps is to optimize the junction structure between source/drain and the channel region and to introduce sufficient dopant in the source/drain and the gate electrode regions to achieve lower parasitic resistance and high inversion capacitance and thereby improving transistor performance.

A first post-sidewall-spacer source/drain ion implant step is a boron or indium implant of a dose between 5E14 and 2E15 ions/cm², preferably 1.7E15 ions/cm² at between 1 and 10 keV, preferably 6 keV. This implant ensures the source/drain regions and the gate electrode regions have low sheet resistance. Sufficient doping level in the gate electrode should be maintained to prevent dopant depletion when a voltage is applied to the gate. Dopant depletion has become a concern as the thickness of the gate dielectric 30 becomes progressively thin that the capacitance associated with it becomes significant compared to the capacitance associated with the dopant depleted layer in the poly-gate electrode 40.

A second post-sidewall-spacer ion implant step is a boron or indium implant of a dose between 1E14 and 2E15 ions/cm², preferably 8E14 ions/cm² at between 2 and 10 keV, preferably 6 keV. The dose and energy is chosen to ensure that the boundary of the source/drain region is not pushed beyond the desirable position and the source/drain junction is adequately graded to keep the GEDL is under a desirably low level.

A third post-sidewall-spacer ion implant step is a boron or indium implant of a dose between 1E13 and 1E14 ions/cm², preferably 5E13 ions/cm², at between 5 and 25 keV, preferably 15 keV. This implant sets the proper dopant distribution profile at the bottom of the source/drain regions, which in turn sets the junction capacitance Cj to a desirably low value. A low junction capacitance is desirable for maintaining superior transistor switching performance.

The three-step post-sidewall-spacer ion implant creates overlapping doping regions depicted in FIG. 2. Region 110 is created by the second-step boron/indium implant, region 120 is created by the first-step boron/indium implant, and region 130 is created by the third-step boron/indium implant. Each ion implant step serves a distinct purpose and the combination of the three implants creates a PMOS that is superior in its Idrive and Ioff performance. Even though the 3 implant steps are designated as the first-step, the second-step, and the third-step implant, the sequence may be changed without deviating from the teaching of this invention. Also, these ion implant conditions are for demonstrative purpose only. Those skilled in the art of semiconductor device fabrication may adapt the concept of the invention and apply it to transistors not identical to the transistor in this embodiment and achieve desirable transistor performance without undue experiments.

1. A semiconductor transistor comprising:
a. a semiconductor substrate with a first upwardly facing surface;
b. a gate electrode formed over the silicon substrate, the gate electrode having two opposing sidewalls;
c. a dielectric member disposed between the semiconductor substrate and the gate electrode;
d. a sidewall spacer disposed on each opposing sidewall and on the first upwardly facing surface;
e. a source/drain region with a second upwardly facing surface disposed in the semiconductor substrate, the second upwardly facing surface substantially coinciding with the first upwardly facing surface, a portion of the second upwardly facing surface underlapping the sidewall spacer, the source/drain region having three ion implanted portions;
f. a first ion implanted portion of the source/drain region having a first dose of dopant, implanted at a first implant energy through a portion of the second upwardly facing surface uncovered by the sidewall spacer, the first dose of dopant being advantageous in setting the Ioff and GEDL of the transistor;
g. a second ion implanted portion of the source/drain region having a second dose of dopant, implanted at a second implant energy through a portion of the second upwardly facing surface uncovered by the sidewall spacer, the second dose of dopant being advantageous in setting the sheet resistance of the source/drain region and the dopant concentration of the channel region and the inversion capacitance of the transistor; and
h. a third ion implanted portion of the source/drain region having a third dose of dopant, implanted at a third implant energy through a portion of the second upwardly facing surface uncovered by the sidewall spacer, the third dose of dopant being advantageous in setting the source/drain junction capacitance of the transistor.

2. A semiconductor transistor according to claim 1, wherein the semiconductor transistor is a PMOS.

3. A semiconductor transistor according to claim 1, wherein the semiconductor transistor is a NMOS.

4. A semiconductor transistor according to claim 1, wherein the gate electrode of the semiconductor transistor further comprise polysilicon material.

5. A semiconductor transistor according to claim 1, wherein the semiconductor substrate comprises silicon material.

6. A process for making a semiconductor transistor, comprising:
a providing a semiconductor substrate with a first upwardly facing surface,
b forming a gate electrode over the silicon substrate, the gate electrode having two opposing sidewalls,
c forming a dielectric member between the semiconductor substrate and the gate electrode,
d forming a sidewall spacer on each opposing sidewall and on the first upwardly facing surface, and
e forming a source/drain region in the semiconductor substrate by an ion implantation process, the source/drain region having three portions and a second upwardly facing surface, the second upwardly facing surface substantially coinciding with the first upwardly facing surface, a portion of the second upwardly facing surface underlapping the sidewall spacer, the ion implantation process including;
(i) implanting into a first portion of the source/drain region with a first dose of dopant, at a first implant energy through a portion of the second upwardly facing surface uncovered by the sidewall spacer, the first dose of dopant being advantageous in setting the Ioff and GEDL of the transistor,
(ii) implanting into a second portion of the source/drain region with a second dose of dopant, at a second implant energy through a portion of the second upwardly facing surface uncovered by the sidewall spacer, the second dose dopant being advantageous in setting the sheet resistance of the source/drain region and the doping concentration of the channel region and the inversion capacitance of the transistor, and
(iii) implanting into a third portion of the source/drain region with a third dose of dopant, at a third implant energy through a portion of the second upwardly facing surface uncovered by the sidewall spacer, the third dose of source/drain dopant being advantageous in setting the source/drain junction capacitance of the transistor.
